(19) United States
(12) Patent Application Publication
(10) Pub. No.: US 2005/0009269 A1
(43) Pub. Date: Jan. 13, 2005

(54) Semiconductor device and method of manufacturing semiconductor device

(76) Inventors: Hiroki Shinkawata, Tokyo (JP); Atsushi Hachisuka, Tokyo (JP); Hiroki Shimano, Tokyo (JP)

Correspondence Address: MCDERMOTT, WILL & EMERY, 600 13th Street, N.W., Washington, DC, 20005-3096, US

(21) Appl. No.: 10/850,051

(22) Filed: May 21, 2004

(30) Foreign Application Priority Data
May 21, 2003 (JP) JP2003-143355

(51) Int. Cl. H01L 21/8242

(52) U.S. Cl. 438/250; 438/393

(57) ABSTRACT

An isolation film is formed in a surface of a substrate 1 in which active regions are formed, to separate the active regions from each other. Subsequently, a portion of the isolation film is removed, to form a recess, which is then filled with a portion of an upper electrode. Also, an insulating film 8 is interposed between the upper electrode and the substrate.

### BACKGROUND OF THE INVENTION

1. Field of the Invention

The present invention relates to a semiconductor device and a method of manufacturing a semiconductor device, and is applicable to a semiconductor device including a planar memory cell, and a method of manufacturing the same, for example.

2. Description of the Background Art

Conventionally, advances in development of a planar memory cell in which a gate electrode and an upper electrode of a capacitor are formed in the same layer have been made.

A typical planar memory cell has a structure in which a gate electrode and an upper electrode of a capacitor are formed on a substrate in which active regions and an isolation film separating the active regions from each other are formed. Further, the upper electrode of the capacitor is formed so as to extend over portions of the active regions and the isolation film (refer to TSMC Fall 2002 Technology Symposium, pp. 58, for example).

In the above described structure, the capacitor is formed in a region where the upper electrode of the capacitor and the active region overlap each other. In this regard, because of a trend for further miniaturization of a semiconductor device in recent years, a surface area of the capacitor has become smaller. This results in reduction of a capacitance of the capacitor, to possibly invite malfunction of the memory cell.

### SUMMARY OF THE INVENTION

It is an object of the present invention to provide a semiconductor device including a memory cell which provides for increase of a capacitance of a capacitor and can properly operate despite miniaturization, and a method of manufacturing the same.

According to a first aspect of the present invention, a semiconductor device includes a substrate, a recess, an insulating film and a conductor. The substrate has a surface in which active regions are formed. The recess is formed in the surface of the substrate, and separates the active regions from one another. The insulating film is formed so as to cover a side face of the recess and the active regions. The conductor is formed on the insulating film and buried in at least an open end of the recess.

A capacitor is formed also in a region where a side face of the recess is situated, so that a capacitance of the capacitor can be increased. Accordingly, it is possible to provide a semiconductor device including a memory cell which can properly operate despite miniaturization of the semiconductor device.

According to a second aspect of the present invention, a method of manufacturing a semiconductor device includes the steps (a), (b), (c) and (d). The step (a) is to prepare a substrate having a surface in which active regions are formed. The step (b) is to form a recess which separates the active regions from each other, in the surface of the substrate. The step (c) is to form an insulating film which extends over a side face of the recess and the active regions. The step (d) is to form a conductor on the insulating film such that the conductor is buried in at least an open end of the recess.

A capacitor is formed also in a region where a side face of the recess is situated, so that a capacitance of the capacitor can be increased. Accordingly, it is possible to manufacture a semiconductor device including a memory cell which can properly operate despite miniaturization of the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a memory cell section.

FIG. 2 is a sectional view of a structure of a semiconductor device according to a first preferred embodiment.

FIGS. 3 through 7 are sectional views for illustrating a method of manufacturing a semiconductor device according to the first preferred embodiment.

FIG. 8 is a sectional view of a structure of a conventional semiconductor device.

FIG. 9 is a sectional view of a structure of a semiconductor device according to a second preferred embodiment.

FIGS. 10 through 13 are sectional views for illustrating a method of manufacturing a semiconductor device according to the second preferred embodiment.

FIG. 14 is a sectional view of a structure of a semiconductor device according to a third preferred embodiment.

FIGS. 15 through 23 are sectional views for illustrating a method of manufacturing a semiconductor device according to the third preferred embodiment.

FIGS. 24, 25 and 26 are sectional views for illustrating a method of manufacturing a semiconductor device according to a fourth preferred embodiment

FIG. 27 is a sectional view of a structure of a semiconductor device according to a fifth preferred embodiment.

FIGS. 28 through 33 are sectional views for illustrating a method of manufacturing a semiconductor device according to the fifth preferred embodiment.

### DESCRIPTION OF THE PREFERRED EMBODIMENTS

Below, the present invention will be described in detail with reference to accompanying drawings which illustrate preferred embodiments of the present invention.

First Preferred Embodiment

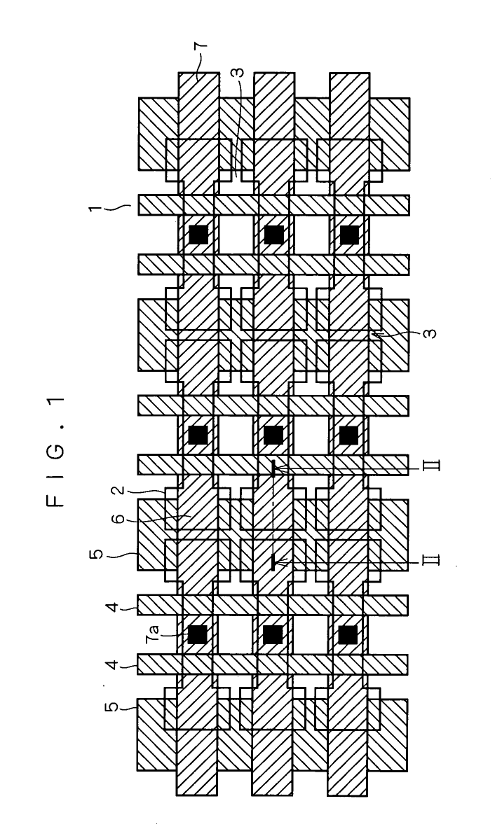

FIG. 1 is a plan view of a planar DRAM, as one example of a semiconductor device according to a first preferred embodiment.

Referring to FIG. 1, a plurality of active regions 2 each shaped like a dumbbell are formed in predetermined regions in a surface of a silicon substrate (which will be hereinafter simply referred to as a “substrate”) 1. It is noted that the expression “a region (portion or the like) in a surface” means a region extending from the surface of the substrate 1 toward an interior of the substrate 1. Also, isolation films 3 for electrically separating the active regions 2 from one another are formed in the surface of the substrate 1. A plurality of gate electrodes 4 are formed on the substrate 1 and across the plurality of active regions 2. The plurality of gate electrodes 4 are arranged in predetermined positions so as to produce a striped pattern (each of the gate electrodes 4 extends in a longitudinal direction on the plane of the drawing sheet of FIG. 1). A plurality of upper electrodes 5 of capacitors are formed in the same layer that includes the gate electrodes 4, and arranged in predetermined positions. Each of the plurality of upper electrodes 5 extends in the same direction as the direction in which each of the gate electrodes 4 extends.

Respective portions of the active regions 2 are covered with the upper electrodes 5 of the capacitors. Then, capacitors 6 of the DRAM are formed in regions where the active regions 2 and the upper electrodes 5 overlap with each other.

Further, an interlayer insulating film is formed over the substrate 1 so as to cover the gate electrodes 4 and the upper electrodes 5, though the interlayer insulating film is not illustrated in FIG. 1. Moreover, bit lines 7 are formed on the interlayer insulating film. Each of the bit lines 7 extends in a direction perpendicular to the direction in which each of the gate electrodes 4 extends (i.e., each of the bit lines 7 extends in a lateral direction on the plane of the drawing sheet of FIG. 1).

Furthermore, bit line contacts 7a for connecting the active regions 2 and the bit lines 7 are formed, which pass through the interlayer insulating film.

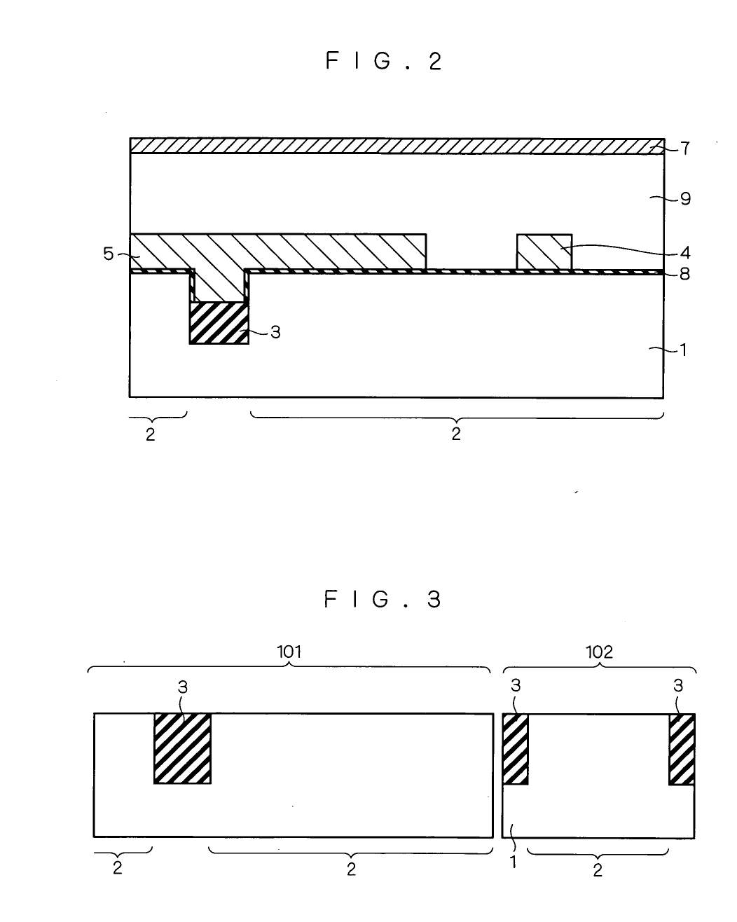

FIG. 2 is a magnified sectional view taken along a line II-II in FIG. 1.

FIG. 2 illustrates a structure in which the active regions 2 and one of the plurality of isolation films 3 for separating the active regions 2 from each other are formed in the surface of the substrate 1. It is noted that a recess is formed in the substrate 1, and the recess is filled with the isolation film 3 and a portion of the upper electrode 5.

More specifically, the recess includes a lower portion which is filled with the isolation film 3 and an upper portion which is filled with the portion of the upper electrode 5. The lower portion of the recess extends from a bottom face of the recess to a level at a predetermined depth from an open top end of the recess. On the other hand, the upper portion of the recess extends from the level at the predetermined depth from the open top end of the recess to a level at which the open top end of the recess is present. Further, an insulating film 8 such as a silicon oxide film is formed on a side face of the upper portion of the recess which is filled with the portion of the upper electrode 5 and on the surface of the substrate 1.

The upper electrode 5 includes the portion with which the upper portion of the recess in the substrate 1 is filled as noted above, and the other portion which extends over a predetermined region of the substrate 1 with the insulating film 8 interposed therebetween. FIG. 2 also illustrates the gate electrode 4 which is formed on the insulating film 8 while being spaced apart from the upper electrode 5.

FIG. 2 further illustrates the interlayer insulating film denoted by a reference numeral “9”, which covers the gate electrode 4, the upper electrode 5 and the insulating film 8. The bit line 7 is formed on a top face of the interlayer insulating film 9 so as to extend in a lateral direction on the plane of the drawing sheet of FIG. 2.

Below, a method of manufacturing a semiconductor device according to a first preferred embodiment will be described in detail with reference to accompanying drawings including sectional views for illustrating respective steps in the manufacturing method. It is noted that the following description will be made about a method of manufacturing a planar embedded DRAM (eDRAM) in which a memory cell section and a logic section are formed on the same substrate, by way of example.

First, the plurality of isolation films 3 are formed in the surface of the substrate 1 in order to electrically separate the active regions 2 from one another as illustrated in FIG. 3, by known trench isolation or the like. It is noted that a section where a memory cell is to be formed is referred to as a “memory cell section 101” and a section where a logic circuit is to be formed is referred to as a “logic section 102”.

Subsequently, an ordinary lithographic process and ion implantation are performed plural times, to form a diffusion region such as a well and a channel of a transistor (not illustrated) within each of respective portions of the substrate 1 which are included in the memory cell section 101 and the logic section 102. Additionally, for the ion implantation, in a case where the transistor of the memory cell is a P-type transistor, N-type impurity ions such as As (arsenic) and P (phosphorus) are implanted into the substrate 1.

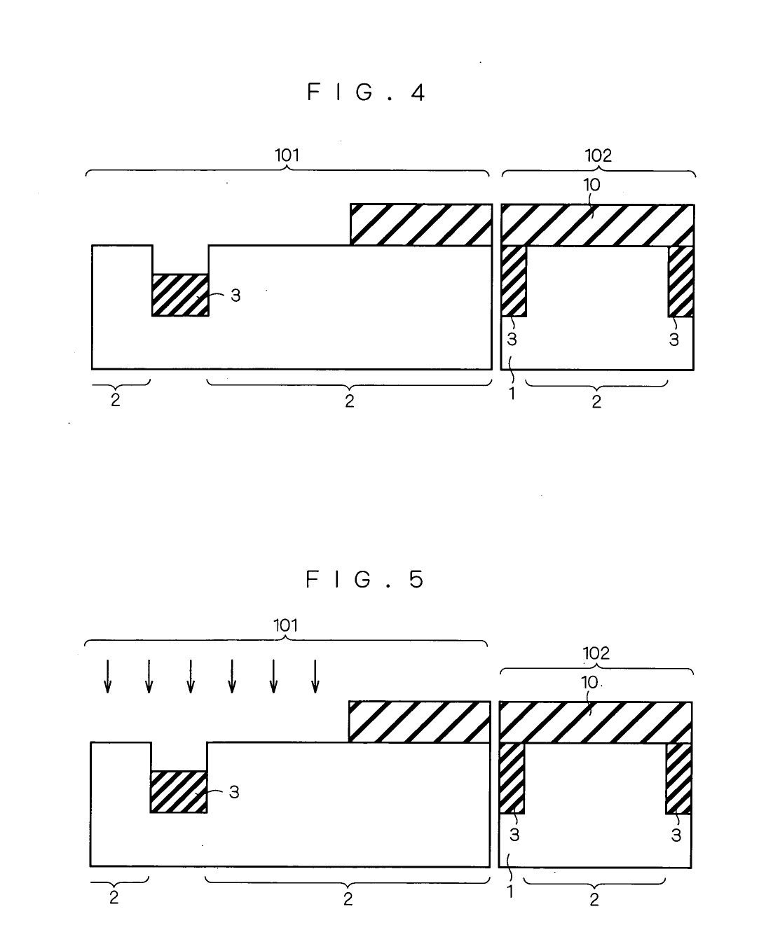

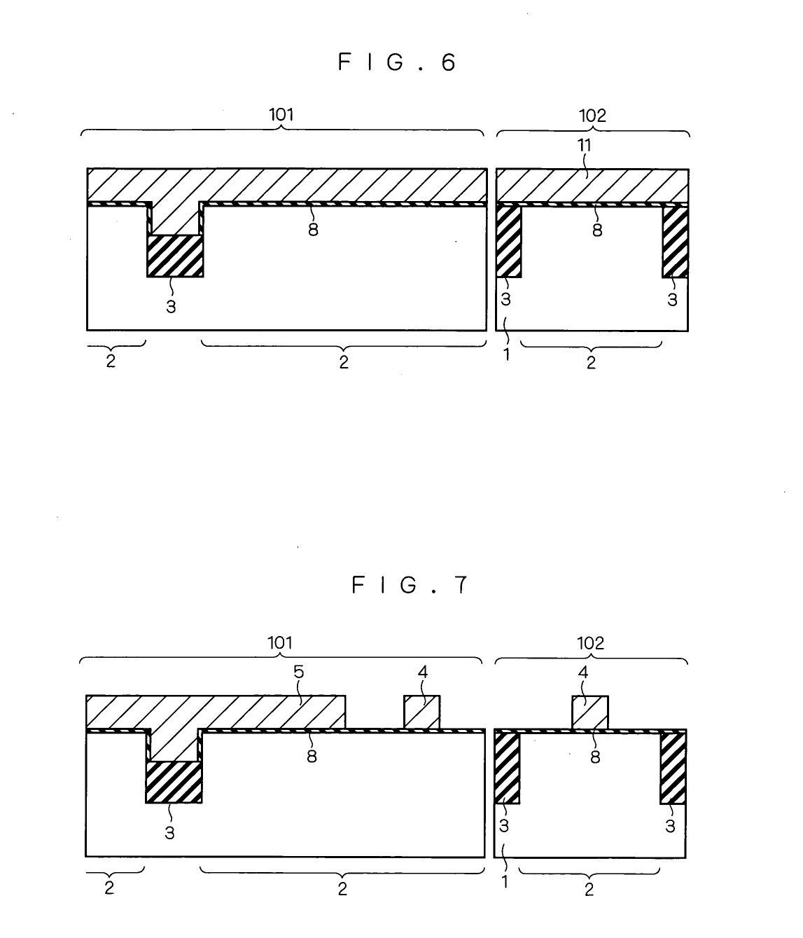

Thereafter, processes for removing a portion of one of the isolation films 3 included in the memory cell section 101 are performed as illustrated in FIG. 4. More specifically, all regions of a resultant structure other than a region where the isolation film 3 of the memory cell section 101 is provided (i.e., a channel region of the transistor of the memory cell, a source/drain region of the transistor of the memory cell, and the whole of the logic section 102) are covered with a resist 10 by a lithographic process. Then, ordinary wet etching is performed, to remove a predetermined upper portion of the isolation film 3 in the memory cell section 101. It is noted that removal of the portion of the isolation film 3 in the memory cell section 101 may be alternatively accomplished by dry etching.

At that time, in a case where the transistor of the memory cell of the memory cell section 101 is a P-type transistor, P-type impurities such as B (boron) may be additionally implanted after the etching for removal of the portion of the isolation film 3 of the memory cell section 101, as illustrated in FIG. 5. Such additional implantation of P-type impurities would serve to enhance an efficiency of usage of a capacitor which is to be formed in a later step.

More specifically, as a result of implantation of the impurities as noted above into a portion in the surface of the substrate 1 in which the capacitor (i.e., the upper electrode 5) is to be formed in a later step, a channel is formed in the portion of the substrate 1 into which the impurities are implanted, at a lower voltage during operation. Accordingly, holes are gathered to the implanted portion of the substrate 1 so that a width of a depletion layer is reduced. This reduces an effective width of a dielectric film of the capacitor, so that the implanted portion of the substrate 1 can more significantly function as a lower electrode of the capacitor. Thus, the efficiency of usage of the capacitor is enhanced.

However, during the additional implantation of the impurities, care should be taken in order to prevent the impurities from being implanted into a portion of the substrate 1 which is present under a bottom face of the isolation film 3 of the memory cell section 101. When a thickness of the isolation film 3 is approximately 0.2 μm, for example, the additional implantation of the impurities should be performed at an energy of approximately 5 keV. Such care is necessary to prevent occurrence of a leakage current under the bottom face of the isolation film 3 of the memory cell section 101.

Then, after the portion of the isolation film 3 of the memory cell section 101 is removed, the resist 10 is removed, first. Subsequently, the insulating film 8 is formed on a side face of a recess formed as a result of the removal of the portion of the isolation film 3 of the memory cell section 101 and on the surface of the substrate 1 by thermal oxidation or the like, as illustrated in FIG. 6. Thereafter, a conductive material 11 such as polysilicon is provided so as to be buried in the recess formed as a result of the removal of the portion of the isolation film 3 of the memory cell section 101 and extend over the insulating film 8, by a CVD process or the like.

Thereafter, a lithographic process is performed for patterning the conductive material 11, to form the upper electrode 5 and the gate electrode 4, as illustrate in FIG. 7. As readily appreciated from FIG. 7, the recess formed as a result of the removal of the portion of the isolation film 3 of the memory cell section 101 is filled with a portion of the upper electrode 5 in the semiconductor device according to the first preferred embodiment.

After formation of the upper electrode 5 and the gate electrode 4, ion implantation is performed on a predetermined region of a resultant structure, to form source/drain regions and the like (not illustrated). Subsequently, the interlayer insulating film 9 covering the gate electrode 4, the upper electrode 5 and the insulating film 8 is deposited, and the bit line 7 is provided on the top face of the interlayer insulating film 9, to thereby complete the semiconductor device illustrated in FIG. 2.

As described above, according to the first preferred embodiment, a portion of the isolation film 3 is removed to form a recess, which is filled with a portion of the upper electrode 5. This can increase a surface area of the capacitor, to thereby increase a capacitance of the capacitor.

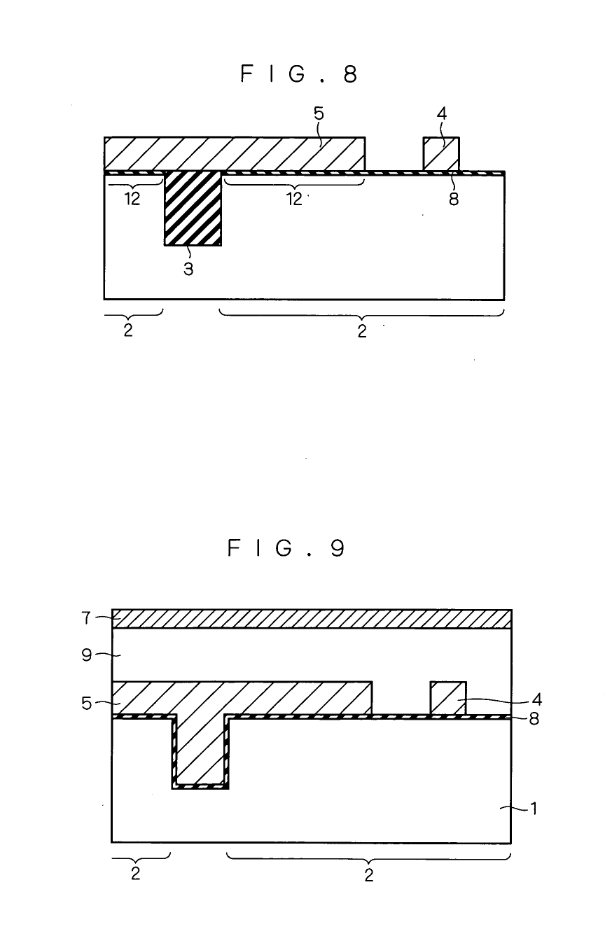

More specifically, in a semiconductor device in accordance with conventional practices illustrated in FIG. 8, a capacitor is formed only in a region 12 where the upper electrode 5 and the active region 2 overlap with each other. In contrast thereto, in the semiconductor device according to the first preferred embodiment, a portion of the isolation film 3 is removed to form a recess, which is filled with a portion of the upper electrode 5. Accordingly, a capacitor is formed also in a region where a side face of the recess is situated, to thereby correspondingly increase a capacitance of the capacitor.

It is noted that a depth of a recess for forming the isolation film 3 is determined in accordance with an isolation voltage of the logic section 102 because of a higher operating voltage of the logic section 102 relative to the memory cell section 101. Since the recess for forming the isolation film 3 is formed in each of the memory cell section 101 and the logic section 102 at the same time, the recess as formed is deeper than is required in the memory cell section 101. Thus, even if a portion of the isolation film 3 of the memory cell section 101 is removed as described above according to the first preferred embodiment, it is possible to easily ensure a necessary isolation voltage for the memory cell section 101.

Further, since the insulating film 8 extends over the side face of the recess formed as result of removal of the portion of the isolation film 3 of the memory cell section 101, a leakage current will not occur in a region where the side face of the recess formed as result of removal of the portion of the isolation film 3 of the memory cell section 101 is situated.

Second Preferred Embodiment

One of features of a semiconductor device according to a second preferred embodiment resides in that an isolation film which has been formed during formation of the semiconductor device is completely removed, and a recess formed as a result of removal of the isolation film is completely filled with a material for an electrode with an insulating film interposed therebetween, to form the upper electrode 5. FIG. 9 illustrates a structure of the semiconductor device according to the second preferred embodiment.

As illustrated in FIG. 9, in the semiconductor device according to the second preferred embodiment, an isolation film which has been formed in the surface of the substrate 1 during formation of the semiconductor device is completely removed, and the insulating film 8 is formed on a side face and a bottom face of a recess formed as a result of removal of the isolation film. Further, the upper electrode 5 is formed on the insulating film 8 so that the recess is completely filled with the upper electrode 5. The structure of the semiconductor device according to the second preferred embodiment is identical to that according to the first preferred embodiment which is illustrated in FIGS. 1 and 2, in all the other respects, and thus further description is believed unnecessary.

Below, a method of manufacturing a semiconductor device according to the second preferred embodiment will be described in detail with reference to accompanying drawings including sectional views for illustrating respective steps in the manufacturing method. It is noted that the following description will be made about a method of manufacturing a planar embedded DRAM (eDRAM) in which a memory cell section and a logic section are formed on the same substrate, by way of example, similarly to the above description in the first preferred embodiment.

First, the substrate 1 which is divided into the memory cell section 101 and the logic section 102 and includes the isolation films 3, in other words, the structure described in the first preferred embodiment with reference to FIG. 3, is prepared. The substrate 1 further includes the active regions 2 electrically separated from one another by the isolation films 3.

Subsequently, an ordinary lithographic process and ion implantation are performed plural times, to form a diffusion region such as a well and a channel of a transistor (not illustrated) within each of respective portions of the substrate 1 which are included in the memory cell section 101 and the logic section 102, in the same manner as described above in the first preferred embodiment with reference to FIG. 3. In the method according to the second preferred embodiment, however, further ion implantation is performed. More specifically, N-type impurity ions such as As or P are implanted into a portion of the substrate 1 under one of the isolation films 3 which is included in the memory cell section 101 and has a thickness of approximately 300 angstroms. The N-type impurity ions are implanted at an energy of approximately 200-300 keV. As a result, an impurity concentration of the implanted portion of the substrate 1 is increased relative to the well which includes N-type impurity ions. The implanted portion is in the well.

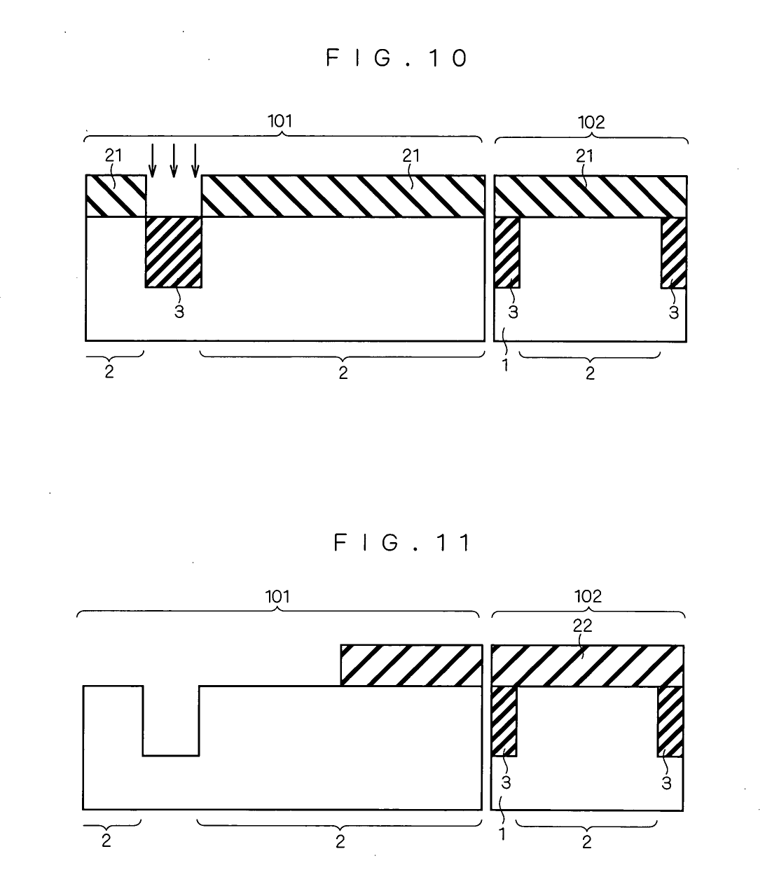

The above noted further ion implantation of the N-type impurity ions such as As and P is performed, with a resist 21 being formed on the substrate 1 by a lithographic process such that the isolation film 3 included in the memory cell section 101 is exposed, as illustrated in FIG. 10. As a result of the further ion implantation, the impurity concentration of the portion of the substrate 1 under the bottom face of the isolation film 3 of the memory cell section 101 is made equal to or higher than 5×10¹³ ion/cm². It is additionally noted that an impurity concentration of the well is equal to approximately 1 ×10¹³ ion/cm².

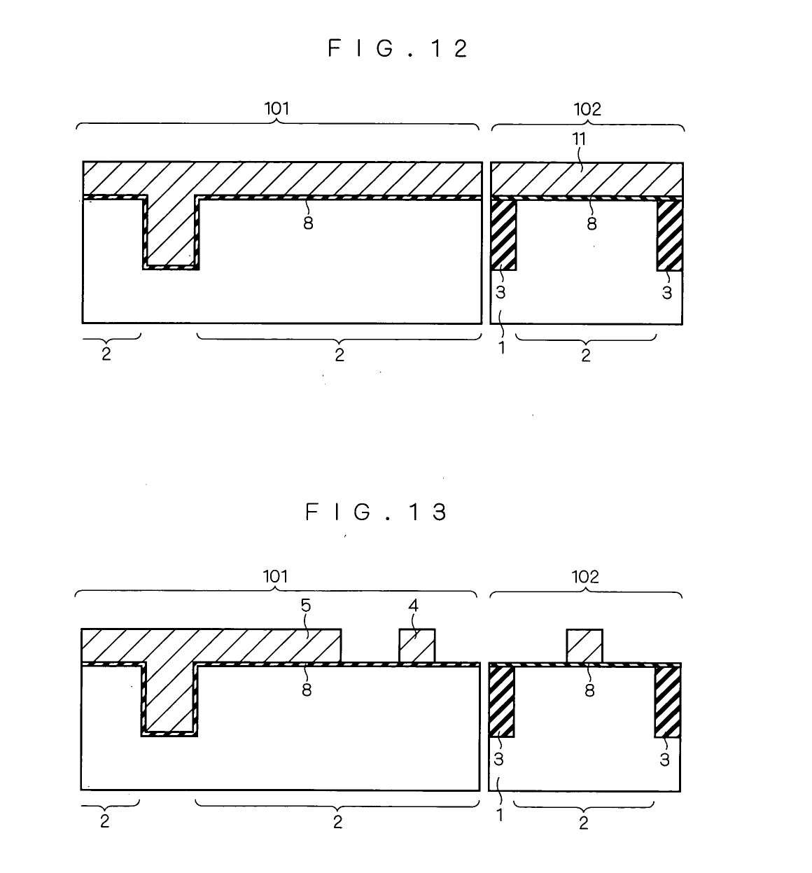

Thereafter, processes for removing the isolation film 3 included in the memory cell section 101 are performed as illustrated in FIG. 11. More specifically, all regions of a resultant structure other than a region where the isolation film 3 of the memory cell section 101 is provided (i.e., a channel region of the transistor of the memory cell, a source/drain region of the transistor of the memory cell, the whole of the logic section 102 and the like) are covered with a resist 22 by a lithographic process. Then, ordinary wet etching is performed, to remove all of the isolation film 3 in the memory cell section 101. It is noted that removal of the isolation film 3 in the memory cell section 101 may be alternatively accomplished by dry etching.

After the isolation film 3 of the memory cell section 101 is removed, the resist 22 is removed, first. Subsequently, the insulating film 8 is formed on a bottom face and a side face of a recess formed as a result of the removal of the isolation film 3 of the memory cell section 101 and on the surface of the substrate 1 by thermal oxidation or the like, as illustrated in FIG. 12. Thereafter, a conductive material 11 such as polysilicon is provided so as to be buried in the recess and extend over the insulating film 8 by a CVD process or the like.

Then, a lithographic process is performed for patterning the conductive material 11, to form the upper electrode 5 and the gate electrode 4, as illustrate in FIG. 13. As readily appreciated from FIG. 13, the recess formed as a result of the removal of the isolation film 3 of the memory cell section 101 is completely filled with a portion of the upper electrode 5 in the semiconductor device according to the second preferred embodiment.

After formation of the upper electrode 5 and the gate electrode 4, ion implantation is performed on a predetermined region of a resultant structure. Thereafter, the interlayer insulating film 9 covering the gate electrode 4, the upper electrode 5 and the insulating film 8 is deposited, and the bit line 7 is provided on a top face of the interlayer insulating film 9, to thereby complete the semiconductor device illustrated in FIG. 9.

As described above, in the semiconductor device according to the second preferred embodiment, the isolation film 3 included in the memory cell section 101 is completely removed to form a recess, which is filled with a portion of the upper electrode 5. This can result in a larger surface area of the capacitor than that in the structure according to the first preferred embodiment, to correspondingly increase a capacitance of the capacitor.

In the meantime, as the thickness of the insulating film 8 becomes smaller, a leakage current is more likely to flow under the recess formed as a result of the removal of the isolation film 3 of the memory cell section 101. In this regard, flow of a leakage current under the recess can be suppressed in the structure according to the first preferred embodiment because a portion of the isolation film 3 remains un-removed in the memory cell section 101, and a thickness of the remaining portion of the isolation film 3 is equal to with a thickness of approximately 1000-2000 angstroms, for example.

In contrast thereto, in the structure according to the second preferred embodiment, only the insulating film 8 with such a small thickness as is equal to approximately 30 angstroms is formed on the bottom face of the recess formed as a result of the removal of the isolation film 3 of the memory cell section 101. Such film thickness on the bottom face of the recess could not effectively suppress flow of a leakage current under the recess.

In view of this, the further ion implantation of N-type impurity ions is performed as described above with reference to FIG. 10. The further ion implantation serves to increase the impurity concentration of the portion under the isolation film 3 (or the recess formed as a result of the removal of the isolation film 3 in the final structure) of the memory cell section 101 relative to the well.

A type of a channel formed in the portion with the high impurity concentration can not be easily inverted, to thereby effectively suppress flow of a leakage current in the portion. Further, since the insulating film 8 extends over the side face of the recess formed as result of removal of the isolation film 3 of the memory cell section 101, a leakage current will not occur in a region where the side face of the recess formed as result of removal of the isolation film 3 of the memory cell section 101 is situated.

Third Preferred Embodiment

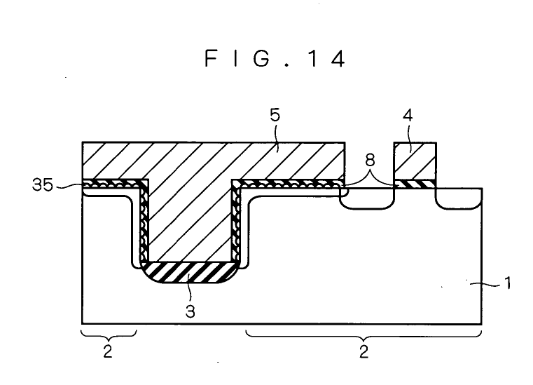

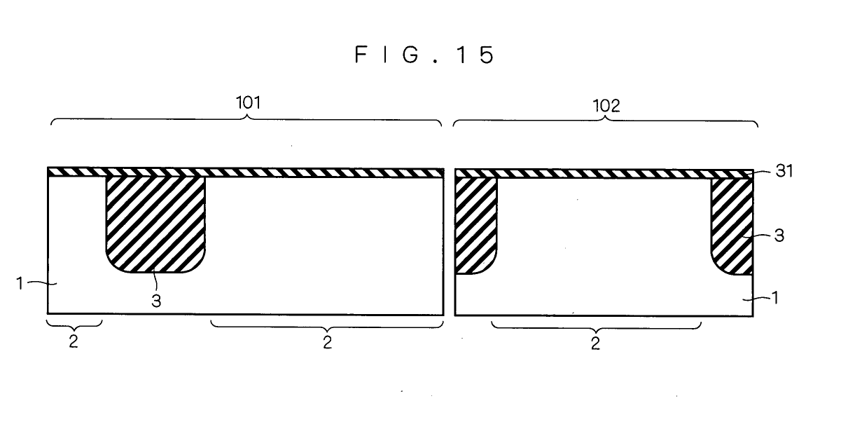

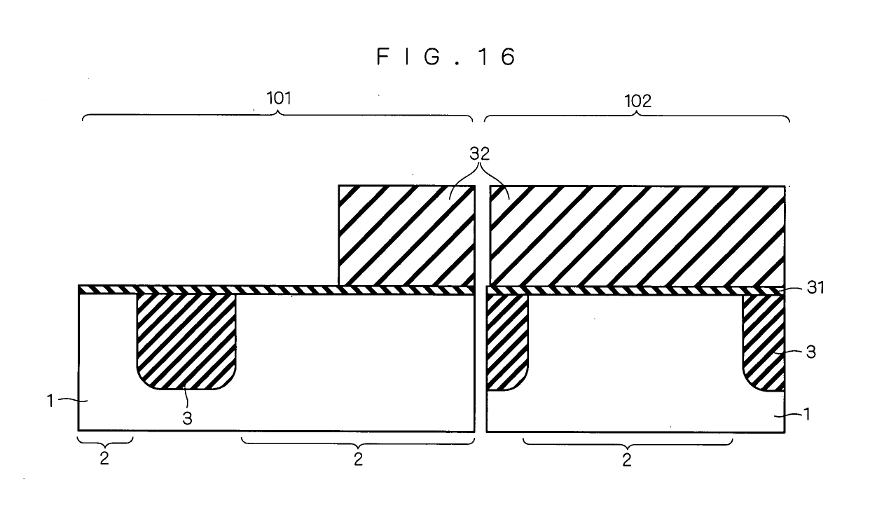

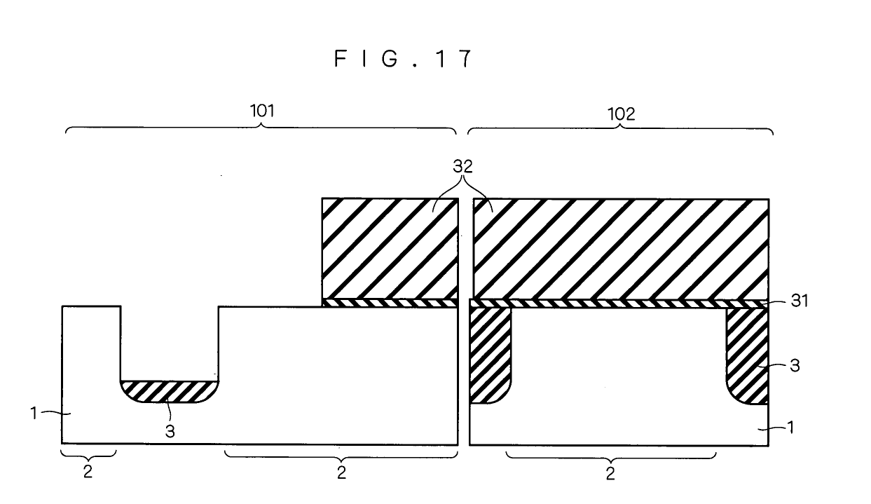

One of features of a semiconductor device according to a third preferred embodiment resides in that a region of a surface of the substrate 1 and a side face of a recess, both of which are covered with the upper electrode 5, are roughened. FIG. 14 shows an essential aspect of a structure of the semiconductor device according to the third preferred embodiment.

As shown in FIG. 14, in the semiconductor device according to the third preferred embodiment, a portion of the isolation film 3 formed in the surface of the substrate 1 is removed. Then, a rough polysilicon 35 is formed on a side face of a recess formed as a result of removal of the portion of the isolation film 3 and on a region of the surface of the substrate 1. Further, the upper electrode 5 is formed so as to cover the rough polysilicon 35 with the insulating film 8 interposed therebetween.

A recess initially formed for formation of the isolation film 3 is completely filled with the remaining portion of the isolation film 3 and a portion of the upper electrode 5. Moreover, the gate electrode 4 is formed on the substrate 1 with the insulating film 8 interposed therebetween, while being spaced apart from the upper electrode 5, as shown in FIG. 14.

Below, a method of manufacturing a semiconductor device according to the third preferred embodiment will be described in detail with reference to accompanying drawings including sectional views for illustrating respective steps in the manufacturing method. It is noted that the following description will be made about a method of manufacturing a planar embedded DRAM (eDRAM) in which a memory cell section and a logic section are formed on the same substrate, by way of example, similarly to the above description in the first or second preferred embodiment.

First, the substrate 1 which is divided into the memory cell section 101 and the logic section 102 and includes the isolation films 3, in other words, the structure described in the first preferred embodiment with reference to FIG. 3, is prepared. The substrate 1 further includes the active regions 2 electrically separated from one another by the isolation films 3.

Subsequently, an insulating film 31 is formed on the substrate 1 as illustrated in FIG. 15. The insulating film 31 is made of a material identical to a material forming the isolation film 3, for example. The insulating film 31 is formed so as to extend over the isolation film 3 also.

After formation of the insulating film 31, a resist 32 is formed on the insulating film 31 which has been formed on the substrate 1 as illustrated in FIG. 15. Then, an ordinary lithographic process is performed on the resist 32. As a result, the resist 32 is patterned to have a predetermined shape as illustrated in FIG. 16. In particular, the resist 32 is patterned such that a portion of the insulating film 31 where the capacitor 6 is to be formed in a later step is exposed.

Thereafter, ordinary wet etching is performed using the patterned resist 32 as a mask as illustrated in FIG. 17. This etching results in removal of the exposed portion of the insulating film 31 and a predetermined upper portion of the isolation film 3 of the memory cell section 101. The removal of the portion of the insulating film 31 and the portion of the isolation film 3 may alternatively be accomplished by dry etching.

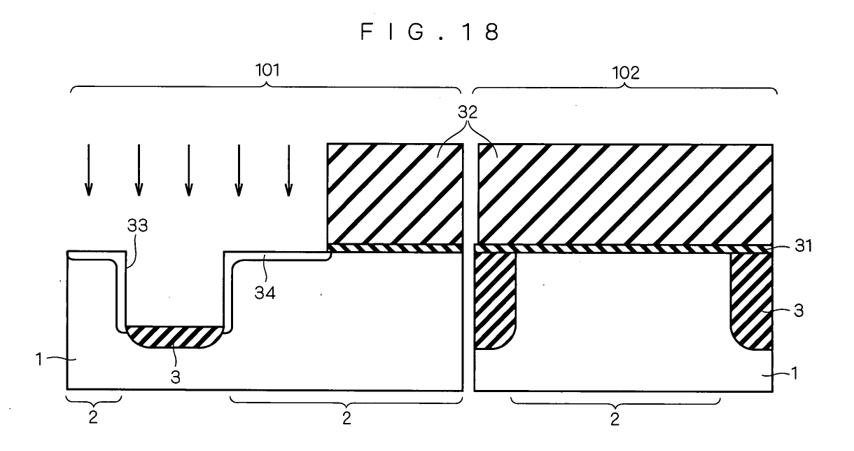

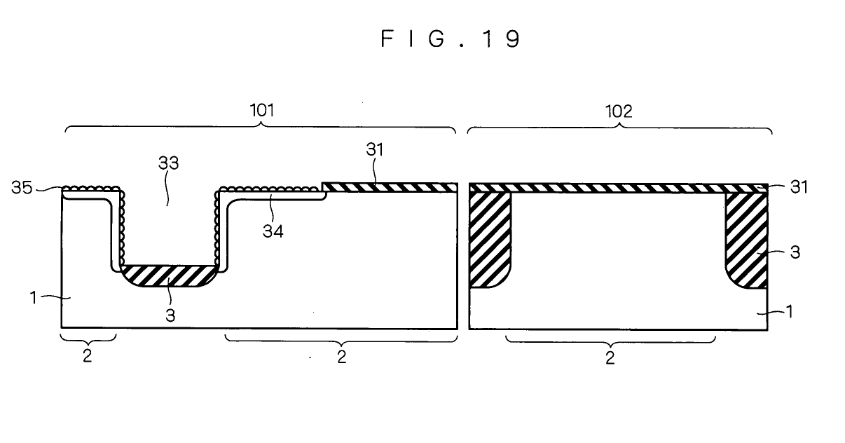

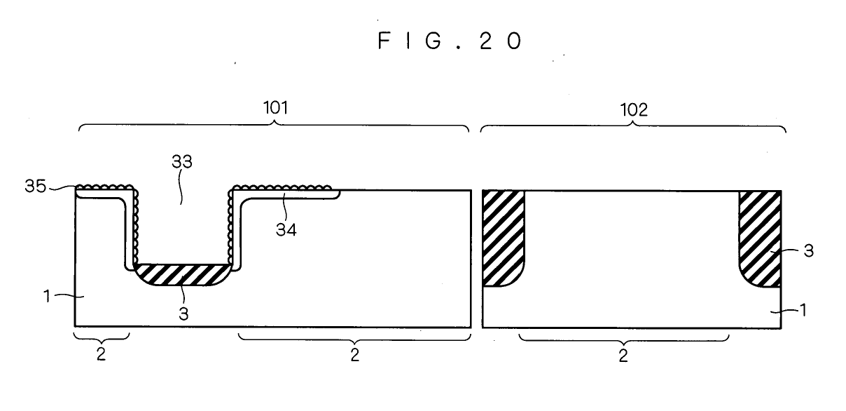

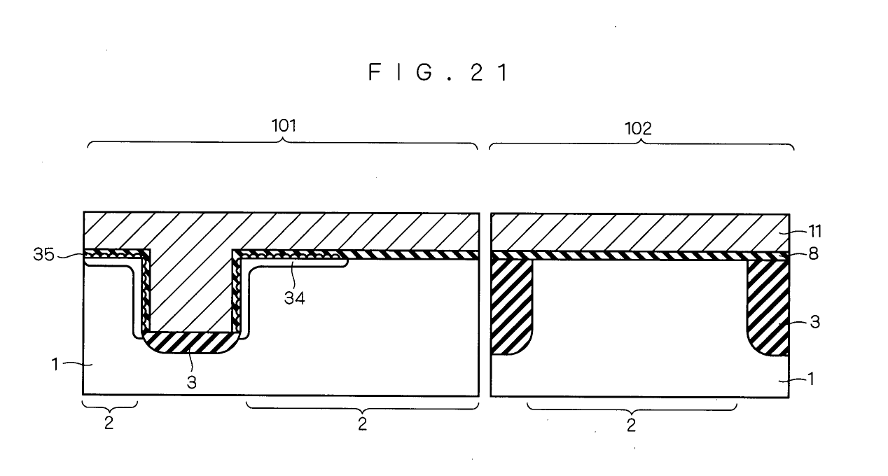

Then, impurity ions are implanted using the patterned resist 32 as a mask as illustrated in FIG. 18. This ion implantation results in formation of region 34 containing impurities in a portion in an exposed region of the surface of the substrate 1 and a portion in a side face of a recess 33 formed in the substrate 1 as a result of removal of the portion of the isolation film 3 of the memory cell section 101.

The impurity ions implanted at this stage are of the same type as ion impurities used for implantation into the upper electrode 5 which is to be formed in a later step. For example, in a case where a transistor of a memory cell of the memory cell section 101 is a P-type transistor, P-type impurities such as B (boron) are implanted.

The ion implantation serves to enhance an efficiency of usage of the capacitor 6 which is to be formed in a later step (so that C (capacitance)-V (voltage) characteristics of the capacitor 6 is improved).

After the ion implantation, the resist 32 is removed.

Subsequently, the rough polysilicon 35 is formed on the exposed region of the surface of the substrate 1 and the side face of the recess 33 which are not covered with the insulating film 31. FIG. 19 illustrates a state where the rough polysilicon 35 is formed on the region of the surface of the (silicon) substrate 1 and the side face of the recess 33, both of which the upper electrode 5 formed in a later step is to extend over.

It is noted that the rough polysilicon 35 can be formed by a method described in Toru Tatsumi et al., “Formation mechanism of hemispherical grains of polysilicon, Applied Physics, Vol. 61, No. 11, pp.1147-1151, 1992, for example.

After the rough polysilicon 35 is formed, the insulating film 31 on the substrate 1 is removed by either dry etching or wet etching. FIG. 20 illustrates a state where the insulating film 31 is removed.

Then, the insulating film 8 is formed so as to extend over the side face of the recess 33 from which the portion of the isolation film 3 of the memory cell section 101 has been removed and the surface of the substrate 1 by thermal oxidation or the like, as illustrated in FIG. 21. Thereafter, the conductive material 11 such as polysilicon is provided on the insulating film 8 by a CVD process or the like. The conductive material 11 is buried in the recess 33.

In the meantime, for formation of the insulating film 8 and the conductive material 11, a heat treatment or annealing is performed. Accordingly, the impurities contained in the region 34 diffuse throughout the region 34, as well as diffuse into the rough polysilicon 35 during the heat treatment or the annealing.

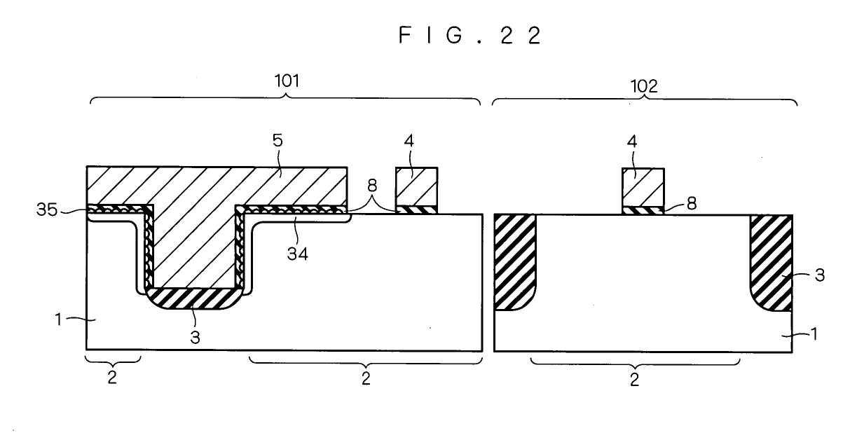

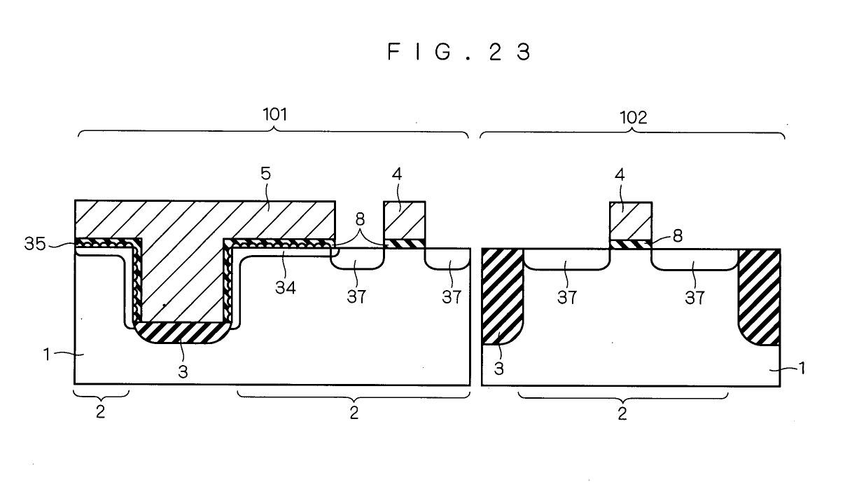

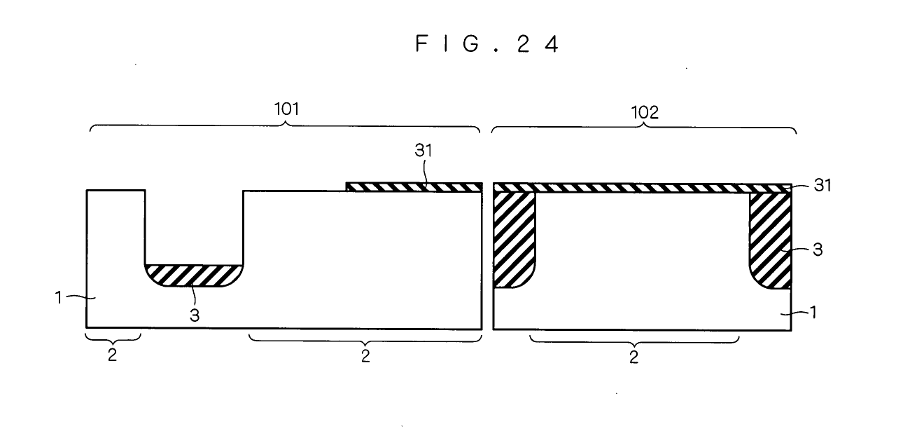

After the conductive material 11 is provided, the conductive material 11 and the insulating film 8 are patterned by an ordinary lithographic process. As a result, the upper electrode 5 and the gate electrode 4 are formed as illustrated in FIG. 22. Every portion of the recess 33 formed in the substrate 1 is filled by formation of the upper electrode 5.

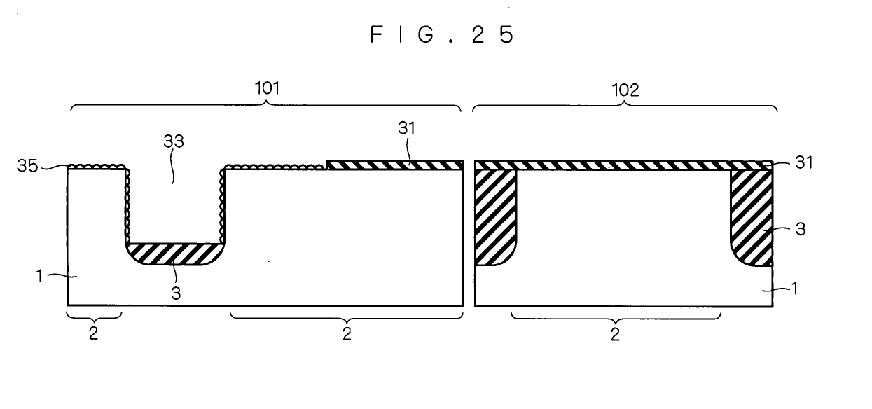

Thereafter, impurity ions are implanted into regions of the surface of the substrate 1 which are present on opposite sides of the gate electrode 4. Further, a heat treatment is performed, to allow the impurity ions to diffuse. As a result, source/drain regions 37 are formed in portions in the surface of the substrate 1 which are present on opposite sides of the gate electrode 4, respectively, as illustrated in FIG. 23.

In the semiconductor device according to the third preferred embodiment, the rough polysilicon 35 is formed on a region of the surface of the substrate 1 and the side face of the recess 33 formed as a result of removal of the portion of the isolation film 3 of the memory cell section 101, both of which the capacitor 6 is to extend over, as illustrated in FIGS. 14, 23 and the like. Hence, a surface area of a lower electrode of the capacitor 6 is increased.

Accordingly, the semiconductor device according to the third preferred embodiment allows for a larger capacitance of the capacitor 6 than that of the capacitor 6 in the semiconductor device according to the first preferred embodiment, by virtue of formation of the rough polysilicon 35.

Fourth Preferred Embodiment

As described above in the first and the third preferred embodiments, the region containing impurities (the region 34 in the third preferred embodiment) is formed in the substrate 1 and the recess formed as a result of removal of the portion of the isolation film 3 of the memory cell section 101 (the recess 33 in the third preferred embodiment), in order to enhance an efficiency of a usage of the capacitor 6 (so that the C (capacitance)-V (voltage) characteristics of the capacitor 6 is improved) (refer to FIG. 18).

In the manufacturing method according to the third preferred embodiment, the region 34 is formed prior to formation of the rough polysilicon 35.

In contrast thereto, one of features of a method of manufacturing a semiconductor device according to a fourth preferred embodiment resides in that the region 34 is formed after the rough polysilicon 35 is formed. Below, the method of manufacturing a semiconductor device according to the fourth preferred embodiment will be described in detail.

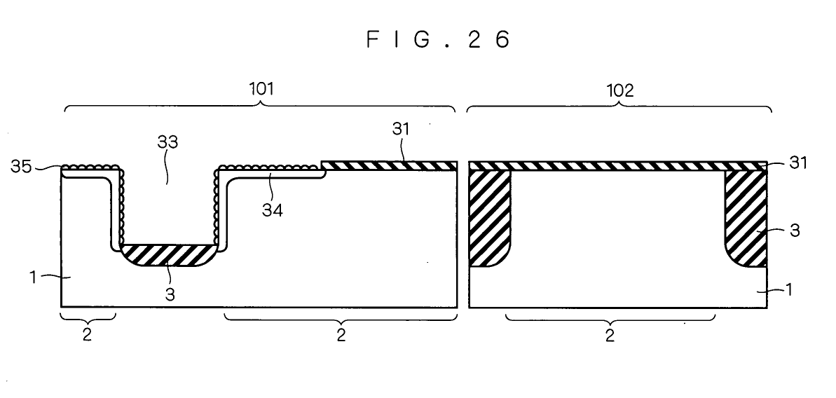

First, the steps illustrated in FIGS. 15, 16 and 17 are performed in the same manner as described above in the third preferred embodiment. Thereafter, the resist 32 is removed from a structure of the semiconductor substrate under manufacture illustrated in FIG. 17. FIG. 24 illustrates a state where the resist 32 is removed.

Subsequently, the rough polysilicon 35 is formed selectively on a portion of the substrate 1 illustrated in FIG. 24. More specifically, the rough polysilicon 35 is formed on an exposed region of a surface of the substrate 1 and a side face of the recess 33 which are not covered with the insulating film 31, as illustrated in FIG. 25. Processes for forming the rough polysilicon 35 are substantially identical to those described above in the third preferred embodiment.

Then, a structure of the semiconductor device under manufacture illustrated in FIG. 25 is carried into a furnace or a lamp anneal system. In a case where a transistor of a memory cell of the memory cell section 101 is an N-type transistor, gas containing N-type impurities (PH₃ gas, for example) are introduced into the furnace or the lamp anneal system. Annealing is performed on the carried structure while PH₃ gas or the like is kept being introduced. The annealing at this time is performed at a temperature in a range of about 700 degrees to 800 degrees.

As a result of the annealing described above, the N-type impurities are doped, and diffuse, into a portion in the surface of the substrate 1 and a portion in the side face of the recess 33, both of which are to be covered with the upper electrode 5 formed in a later step. Accordingly, the region 34 which contains impurities is formed in the portion in the surface of the substrate 1 and the portion in the side face of the recess 33, both of which are to be covered with the upper electrode 5 formed in a later step, as illustrated in FIG. 26. Further, also the rough polysilicon 35 contains N-type impurities after the annealing.

Thereafter, the steps illustrated in FIGS. 20, 21, 22 and 23 are performed in the same manner as described above in the third preferred embodiment.

The above described method of manufacturing a semiconductor device according to the fourth preferred embodiment allows a predetermined portion of the substrate 1 to contain impurities after the rough polysilicon 35 is formed.

On the other hand, a method in which the rough polysilicon 35 is first formed and then impurity ions are implanted may be thought of. However, this method has disadvantages of reducing the surface roughness of the rough polysilicon 35 due to the implantation of impurity ions. The reduction of the surface roughness of the rough polysilicon 35 in a semiconductor device manufactured by this method would lead to reduction of the capacitance of the capacitor 6 as compared to that in a semiconductor device manufactured by the method according to the third preferred embodiment.

However, by utilizing the manufacturing method according to the fourth preferred embodiment, it is possible to form the region 34 after the rough polysilicon 35 is formed without reducing the capacitance of the capacitor 6.

Fifth Preferred Embodiment

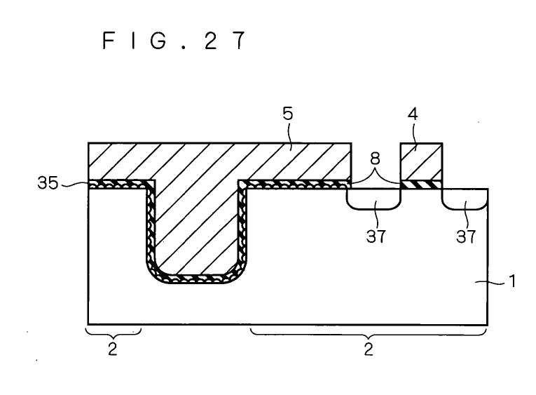

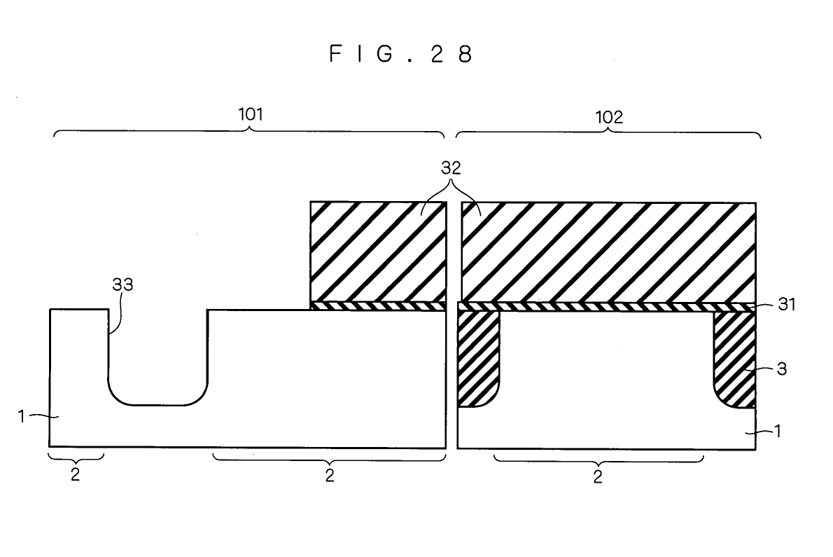

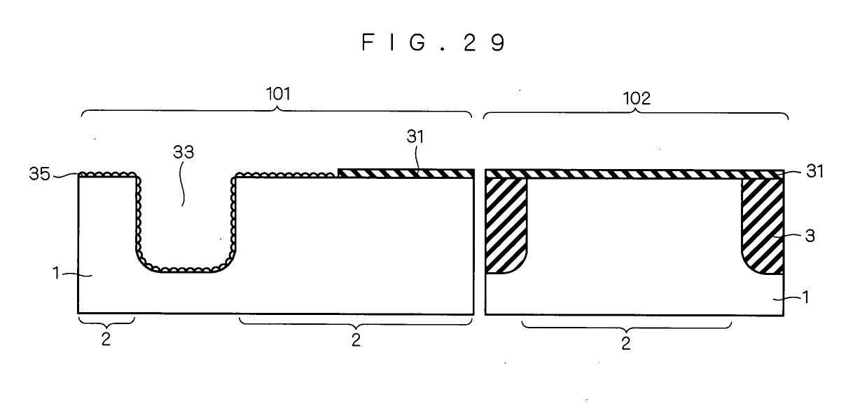

One of features of a semiconductor device according to a fifth preferred embodiment resides in that a region of the surface of the substrate 1 and a side face and a bottom face of a recess in the substrate 1, all of which are covered with the upper electrode 5, are roughened. FIG. 27 shows an essential aspect of a structure of the semiconductor device according to the fifth preferred embodiment.

As shown in FIG. 27, in the semiconductor device according to the fifth preferred embodiment, an isolation film which has been formed in the surface of the substrate 1 during formation of the semiconductor device is completely removed, so that a recess is formed. Then, the rough polysilicon 35 is formed on a side face and a bottom face of the recess and a region of the surface of the substrate 1. The upper electrode 5 is formed so as to cover the rough polysilicon 35 with the insulating film 8 interposed therebetween.

The recess is completely filled with a portion of the upper electrode 5. Also, the gate electrode 4 is formed on the substrate 1 with the insulating film 8 interposed therebetween, while being spaced apart from the upper electrode 5 as shown in FIG. 27.

Below, a method of manufacturing a semiconductor device according to the fifth preferred embodiment will be described in detail with reference to accompanying drawings including sectional views for illustrating respective steps in the manufacturing method. It is noted that the following description will be made about a method of manufacturing a planar embedded DRAM (eDRAM) in which a memory cell section and a logic section are formed on the same substrate, by way of example, similarly to the above description in the preferred embodiments.

First, the substrate 1 which is divided into the memory cell section 101 and the logic section 102 and includes the isolation films 3, in other words, the structure described in the first preferred embodiment with reference to FIG. 3, is prepared. The substrate 1 further includes the active regions 2 electrically separated from one another by the isolation films 3. Subsequently, the steps described above in the third preferred embodiment with reference to FIGS. 15 and 16 are performed.

Thereafter, ordinary wet etching is performed using the patterned resist 32 as a mask as illustrated in FIG. 28. This etching results in removal of an exposed region of the surface of the insulating film 31 and all of the isolation film 3 of the memory cell section 101. The removal of the exposed portion of the insulating film 31 and the isolation film 3 may alternatively be accomplished by dry etching. After the etching for removing the exposed portion of the insulating film 31 and the isolation film 3, the resist 32 is removed.

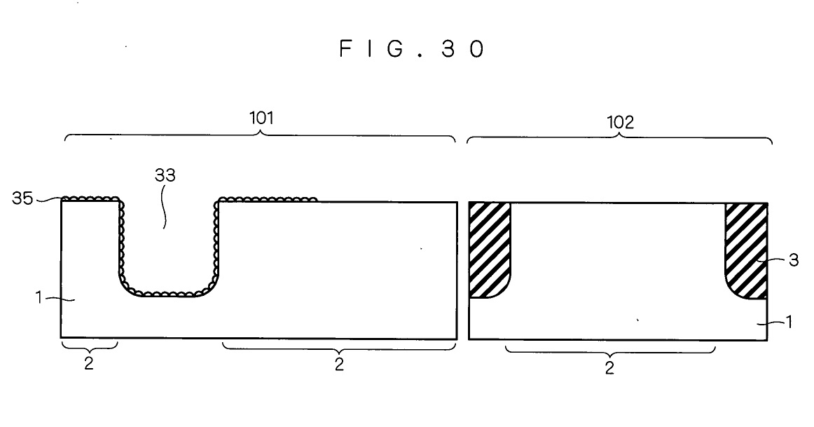

Subsequently, the rough polysilicon 35 is formed on an exposed region of the surface of the substrate 1 and a side face and a bottom face of the recess 33 which are not covered with the insulating film 31. FIG. 29 illustrates a state where the rough polysilicon 35 is formed on a region of the surface of the (silicon) substrate 1 and the side face and the bottom face of the recess 33, all of which the upper electrode 5 formed in a later step is to extend over.

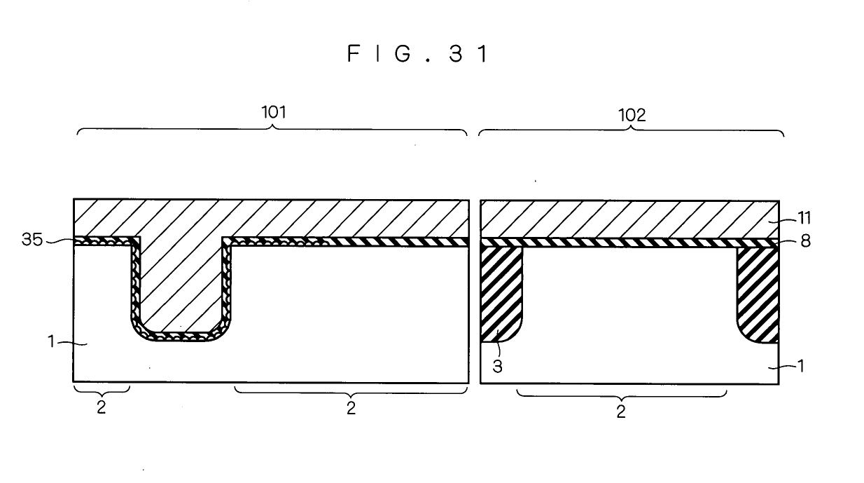

Then, the insulating film 31 on the substrate 1 is removed by either dry etching or wet etching. FIG. 30 illustrates a state where the insulating film 31 is removed.

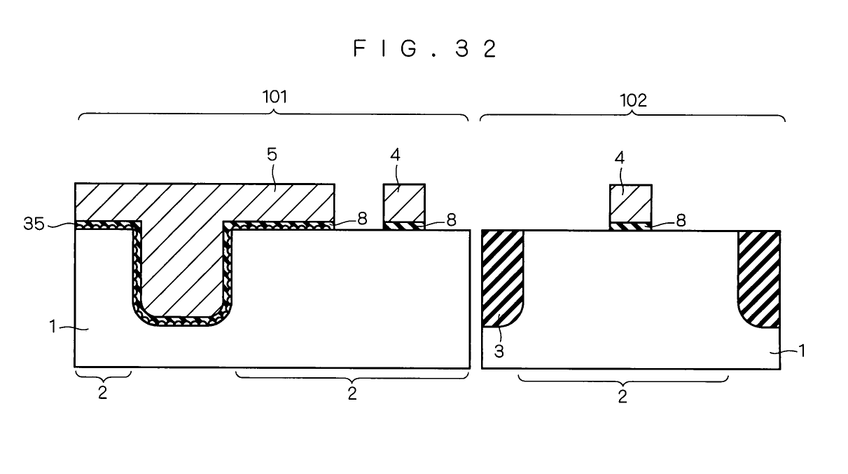

After the insulating film 31 is removed, the insulating film 8 is formed over the bottom face and the side face of the recess 33 from which the isolation film 3 of the memory cell section 101 has been removed and the surface of the substrate 1 by thermal oxidation or the like, as illustrated in FIG. 31. Thereafter, a conductive material 11 such as polysilicon is provided so as to be buried in the recess 33 and extend over the insulating film 8 by a CVD process or the like.

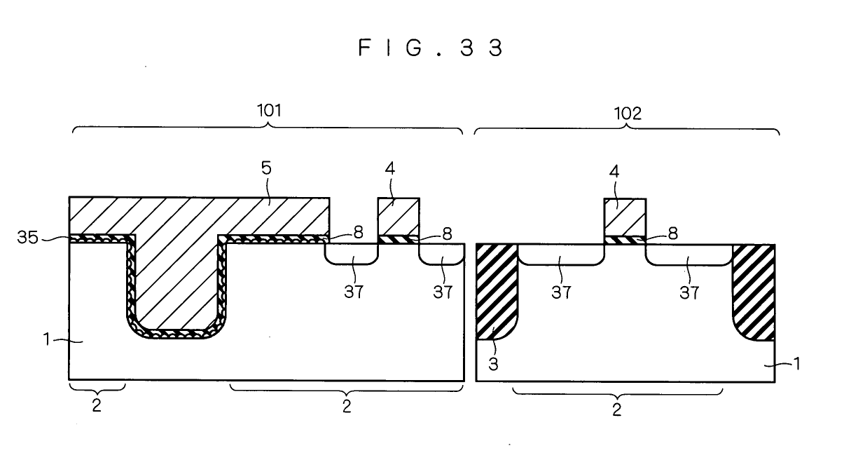

Then, an ordinary lithographic process is performed for patterning the conductive material 11 and the insulating film 8. As a result, the upper electrode 5 and the gate electrode 4 are formed as illustrate in FIG. 32. The recess 33 formed in the substrate 1 is completely filled with a portion of the upper electrode 5.

Thereafter, impurity ions are implanted into regions of the surface of the substrate 1 which are present on opposite sides of the gate electrode 4 . Further, a heat treatment is performed, to allow the impurity ions to diffuse. As a result, the source/drain regions 37 are formed in portions in the surface of the substrate 1 which are present on opposite sides of the gate electrode 4, respectively, as illustrated in FIG. 33.

In the semiconductor device according to the fifth preferred embodiment, the rough polysilicon 35 is formed on the region of the surface of the substrate 1 and the side face and the bottom face of the recess 33 formed as a result of removal of the isolation film 3 of the memory cell section 101, all of which the capacitor 6 is to extend over, as illustrated in FIGS. 27, 33 and the like. The rough polysilicon 35 is formed on not only the region of the surface of the substrate and the side face of the recess 33, but also the bottom face of the recess 33 in the semiconductor device according to the fifth preferred embodiment. Accordingly, a surface area of a lower electrode of the capacitor 6 in the semiconductor device according to the fifth preferred embodiment is larger than that in the semiconductor device according to the third preferred embodiment by an area of the bottom face of the recess 33.

Hence, the semiconductor device according to the fifth preferred embodiment allows for a larger capacitance of the capacitor 6 than that of the capacitor 6 in the semiconductor device according to the third preferred embodiment.

It is additionally noted that a high dielectric constant insulating film can be employed as the insulating film 8 in each of the above described preferred embodiments. To employ a high dielectric constant insulating film as the insulating film 8 would increase the capacitance of the capacitor 6 as compared to a case where SiO₂ is employed as the insulating film 8.

For the high dielectric constant insulating film employable as the insulating film 8, Si₃N₄, Al₂O₃, Ta₂O₅ or the like can be used. However, materials for the high dielectric constant insulating film are not limited to those cited above in the present invention. Any material having a relative dielectric constant higher than that of SiO₂ (approximately equal to 4) can be used for the high dielectric constant insulating film.

In the meantime, a high dielectric constant insulating film which contains a metallic element and polysilicon are unsuited to each other as is well known. To take this fact into account, when a material containing a metallic element such as Al₂O₃ or Ta₂O₅ is used for the high dielectric constant insulating film, it is preferable to employ a metallic material for the conductive material 11.

By doing so, it is possible to suppress leakage which is likely to occur in the high dielectric constant insulating film when polysilicon is employed as the conductive material 11.

For the metallic material employable as the conductive material 11, a material containing Ti, Ir, Ru or the like can be used, for example.

While the invention has been shown and described in detail, the foregoing description is in all aspects illustrative and not restrictive. It is therefore understood that numerous modifications and variations can be devised without departing from the scope of the invention.

1. A semiconductor device comprising:
a substrate having a surface in which active regions are formed;
a recess formed in said surface of said substrate, said recess separating said active regions from one another;
an insulating film formed so as to cover a side face of said recess and said active regions; and
a conductor formed on said insulating film and buried in at least an open end of said recess.

2. The semiconductor device according to claim 1, wherein
said recess includes a lower portion which is filled with an insulator and an upper portion which is filled with said conductor, said lower portion extending from a bottom face of said recess to a level at a predetermined depth from said open end of said recess, and said upper portion extending from said level to said open end of said recess.

3. The semiconductor device according to claim 1, wherein
said insulating film is formed so as to cover also a bottom face of said recess, and
said recess covered with said insulating film is completely filled with said conductor.

4. The semiconductor device according to claim 3, wherein
a well of a predetermined conductivity type is formed in said surface of said substrate, and
an impurity concentration of a region of said well which is present under said bottom face of said recess is higher than other regions of said well.

5. The semiconductor device according to claim 2, wherein
a well of a first conductivity type is formed in said surface of said substrate, and
an impurity of a second conductivity type is contained in at least one of said active regions which is present under said conductor.

6. The semiconductor device according to claim 1 wherein
said surface of said substrate which is covered with said conductor includes a roughened region

7. The semiconductor device according to claim 1, wherein
said insulating film includes a high dielectric constant insulating film.

8. The semiconductor device according to claim 7, wherein
each of said high dielectric constant insulating film and said conductor includes a metallic element.

9. A semiconductor device comprising:
a DRAM circuit;
a logic circuit, wherein
said DRAM circuit and said logic circuit are formed on the same substrate, and
said DRAM circuit includes:
a substrate having a surface in which active regions are formed;
a recess formed in said surface of said substrate, said recess separating said active regions from one another;
an insulating film formed so as to cover a side face of said recess and said active regions; and
a conductor formed on said insulating film and buried in at least an open end of said recess.

10. A method of manufacturing a semiconductor device comprising the steps of:
(a) preparing a substrate having a surface in which active regions are formed;
(b) forming a recess which separates said active regions from each other, in said surface of said substrate;
(c) forming an insulating film which extends over a side face of said recess and said active regions; and
(d) forming a conductor on said insulating film such that said conductor is buried in at least an open end of said recess.

11. The method of manufacturing a semiconductor device according to claim 10, wherein
said step (a) includes a step of preparing said substrate in which a well of a first conductivity type is formed in said surface, and
said method further comprising the steps of:
(e) roughening at least a region of said surface of said substrate which is covered with said conductor formed in said step (d); and
(f) placing said substrate in an atmosphere of gas containing an impurity of a second conductivity type and performing a heat treatment on said substrate, after said step (e).
